(19) United States
(12) Patent Application Publication
(10) Pub. No.: US 2011/0193624 A1
(43) Pub. Date: Aug. 11, 2011

(54) TUNABLE IMPEDANCE INVERTER FOR DOHERTY AMPLIFIER CIRCUIT

(75) Inventors: William Gary Scott, West Melbourne, FL (US); Ramon A. Santo-Tomas, Indialantic, FL (US); George Cabrera, Mason, OH (US); Ronald J. Hash, Palm Bay, FL (US)

(73) Assignee: Harris Corporation

(21) Appl. No.: 12/701,932

(22) Filed: Feb. 8, 2010

(51) Int. Cl. H03F 3/68

(52) U.S. Cl. 330/124 R

(57) ABSTRACT

A tunable impedance inverter is presented for a Doherty amplifier circuit having first and second amplifiers connected in parallel between an input circuit for receiving an input signal and an output circuit for supplying an output signal to a load. An impedance inverter is coupled between the first amplifier and the output circuit. The inverter has an input and an output and a tunable mechanical strip line of variable electrical length interposed between the input and the output. An adjuster adjusts the electrical length of the strip line. The adjuster adjustably varies the electrical length of said pathway to thereby adjust the center frequency of said output signal.

### TECHNICAL FIELD

The present invention relates to RF communication systems and is particularly directed to a modified Doherty amplifier having a tunable impedance inverter.

### BACKGROUND OF THE INVENTION

Television broadcast systems in the ultrahigh-frequency (UHF) region from 470 to 860 MHz are transitioning from analog to digital technology, and broadcasters are taking advantage of digital performance while attempting to keep equipment costs low. Since one of the highest cost components is the transmitter, this is an area where improvements may result in reduced overall costs.

Most digital vector modulation schemes require linear amplification. For many systems, this is achieved using solid state devices. High power tubes are still used for power applications in the kilowatt range, transitioning to a lower cost high frequency solid state transmitter design with enough bandwidth for broadcasting will be needed.

In many of the broadcast applications, the amplifier design may result in a balance between linearity and efficiency. Linear (Class A) amplifiers can provide a linear signal at a significant cost in efficiency. More efficient, non-linear (Class C) amplifiers are available, but these amplifiers tend to suffer from intermodulation and harmonic distortion. A compromise is found in the Doherty amplifier, which utilizes multiple forms of amplifiers to achieve fairly efficient, low distortion amplification of a signal or with a wide range of signal power.

FIG. 1 is a block diagram of a typical prior art Doherty amplifier system 10 employing a linear main amplifier 12 and a non-linear auxiliary amplifier 14 connected together in parallel for receiving an input signal from a signal source 16. The output of the main amplifier 12 can be power combined with the output of the auxiliary amplifier 14 through an impedance inverter 18 (a ¼ wavelength impedance) to a load 20. The quarter wavelength impedance inverter 18 can add a 90° phase lag to the output (current) of the main amplifier 12. Since the auxiliary amplifier 14 may be constructed to lag the main amplifier current by 90°, then the two currents (power) add in phase.

The conventional Doherty amplifier, as presented in FIG. 1, is limited in operation to approximately a 10% bandwidth due to the necessary incorporation of a fixed ¼ wavelength transmission line structure.

Prior art of interest includes the U.S. patents to Kwon U.S. Pat. No. 7,109,790; Dittmer et al. U.S. Pat. No. 7,248,110 and Wong et al. U.S. Pat. No. 7,295,074.

### SUMMARY OF THE INVENTION

In accordance with one aspect of the present invention, a tunable impedance inverter is presented for a Doherty amplifier circuit having first and second amplifiers connected in parallel between an input circuit for receiving an input signal and an output circuit for supplying an output signal to a load. An impedance inverter is coupled between the first amplifier and the output circuit and a tunable strip line of variable electrical length is interposed between the input and the output of the inverter. An adjuster serves to adjust the electrical length of the strip line. The adjuster adjustably varies the electrical length of the pathway to thereby adjust the center frequency of the output signal.

In accordance with another aspect of the invention, an improved Doherty power amplifier circuit is presented, which includes first and second amplifiers. An impedance inverter is provided that combines an output signal of the first amplifier with an output signal of the second amplifier. The inverter has an input and an output and an adjustable, variable length electrical pathway between the input and the output and an adjuster that varies the electrical length of the pathway.

### BRIEF DESCRIPTION OF THE DRAWINGS

The foregoing and other features of the present invention will become apparent to those skilled in the art to which the present invention relates upon consideration of the following description of the invention with reference to the accompanying drawings, wherein:

FIG. 1 is a block diagram illustration of a prior art Doherty amplifier circuit;

FIG. 2 is a block diagram illustration of an improved Doherty amplifier circuit in accordance with the present invention employing a tunable impedance inverter;

FIG. 3 is a perspective view illustrating a tunable impedance inverter constructed in accordance with the present invention;

FIG. 4 is perspective view of the top assembly of the inverter shown in FIG. 3 looking upwards from underneath the inverter;

FIG. 5 is the perspective view of the bottom assembly.

FIG. 6 is a schematic illustration of a portion of the top assembly overlying a portion of the bottom assembly which is useful in the description of the invention herein;

FIG. 7 is an exploded perspective view of the top assembly of the inverter shown in FIG. 3; and

FIG. 8 is an exploded perspective view of the bottom assembly illustrated in FIG. 5.

### DESCRIPTION OF THE PREFERRED EMBODIMENT

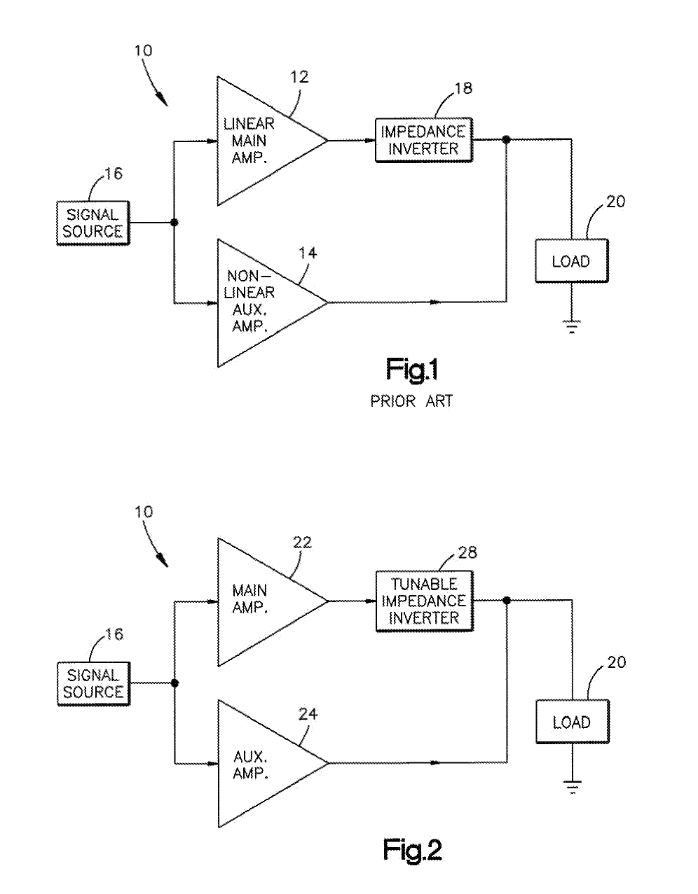

FIG. 2 is a view similar to that of the prior art in FIG. 1 but illustrating the preferred embodiment of the invention. As shown in FIG. 2, a signal source 16 supplies an input signal to a main amplifier 22 and to an auxiliary amplifier 24 connected together in parallel with a tunable impedance inverter 28 and, hence, to the load 20. In this embodiment, the amplifiers may both be non-linear or the main amplifier may be linear as desired. The tunable impedance inverter differs substantially from the inverter 18 which is a fixed quarter wavelength strip line. The inverter 28 is tunable over a wide frequency band such as from 330 MHz to 1 GHz.

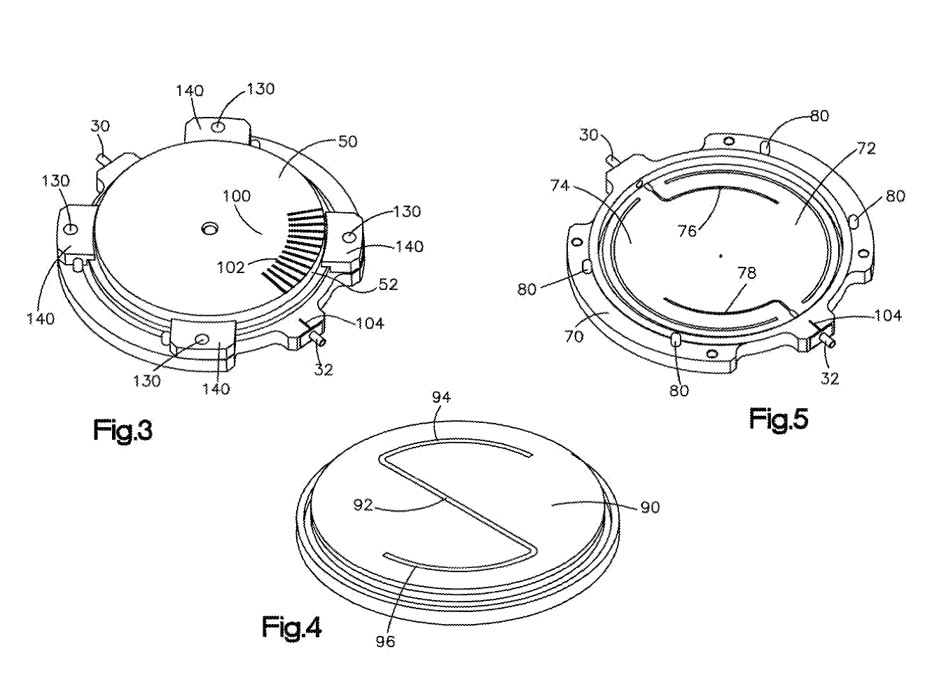

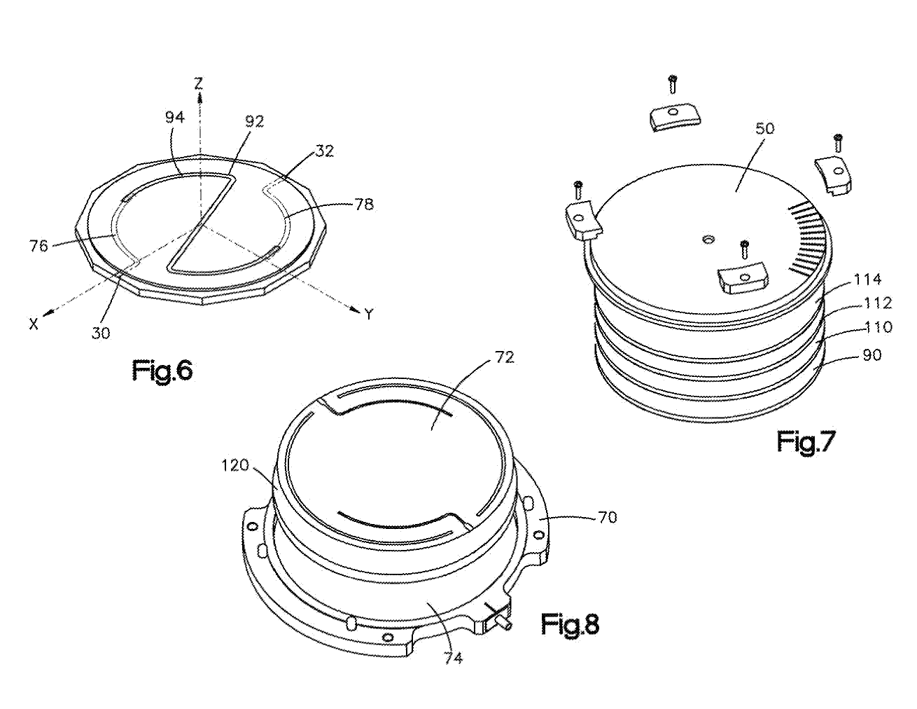

As shown in FIG. 3-8, the inverter 28 is a multi-layered disc-shaped device which, as will be seen, provides a variable electrical length pathway between the input port 30 and the output port 32 when the upper assembly is rotated about the Z axis (see FIG. 6) either in a clockwise direction or in a counterclockwise direction. The top assembly, as best shown in FIGS. 3 and 4, includes a top 50 which is a disc-like aluminum plate having a circular-shaped shelf or flange 52 extending from its lower periphery.

A bottom assembly includes a disc-shaped bottom 70, constructed of aluminum, and is provided with a circular-shaped recess 72 which contains a printed circuit board 74 having a pair of arcuate-shaped conductors 76 and 78 thereon. The conductor 76 extends radially outwardly to the input port 30, whereas the conductor 78 has a portion that extends radially outwardly to the output port 32. Both of these conductors are laid out on the printed circuit board 74 in a normal manner. The bottom assembly also includes four upwardly extending alignment posts 80 which are located circumferentially about the flange 52 (shown in FIG. 3) to maintain alignment of the top 50 during its rotation about the Z axis.

The top 50 has a circular-shaped recess in its lower surface that receives a disc-shaped printed circuit board 90 (FIG. 4). FIG. 4 is a view taken from beneath the top 50 and shows an S-shaped conductor 92. This S-shaped conductor 92 is provided with a central portion 92 and a first end portion 94 and a second end portion 96. In assembly, end portion 94 overlies and electrically contacts a portion of the bottom conductor 76 and end portion 96 overlies and electrically contacts a portion of the bottom conductor 78. The extent to which portions 94 and 96 overlie conductors 76 and 78 is dependent upon the rotational position of the top assembly relative to the bottom assembly. This may be determined by viewing the scale 100 and the scale lines 102 on the upper surface of top 50 relative to the scale line 104 on the bottom 70.

Reference is now made to FIGS. 7 and 8, together with the previous FIGS. 3-6. As shown in FIG. 4, the top assembly includes a printed circuit substrate board 90. This board 90 is shown in FIG. 7 at the bottom of a multi-layered top assembly. Immediately above board 90, there is an adhesive 110 which is interposed between board 90 and a layer of foam 112. Another layer of adhesive 114 is located between foam 112 and the top 50, which is constructed of aluminum. The multi-layered disc-shaped top assembly can be made to rotate about the Z axis (FIG. 6) relative to the bottom assembly.

The bottom assembly is illustrated in FIGS. 5 and 8. This includes a bottom printed circuit substrate board 72 which is carried in a recess 74 in bottom 70. The bottom board 72 is held in place with an adhesive layer 120. The upper assembly is guided in place as it rotates about the Z axis by means of the upstanding alignment posts 80 which are located in a coaxial array as they extend upwardly from the bottom plate 70.

The upper assembly is fastened in place with the lower assembly by means of a plurality (4) screws 130 that extend downwardly through clamps 140 with the screws extending into receiving apertures in the lower plate 70. The clamps, as shown in FIG. 3, have a portion that extends over the circular peripheral flange 52 on the top 50 so as to hold the top assembly in place upon the lower assembly.

In operation, the four screws may be loosened, as with a screwdriver, to release the clamps 140 from their tight engagement with flange 52, so that the top assembly may rotated about the Z axis (as viewed in FIG. 6).

It is to be noted that the conductive pathway between the input port 30 and the output port 32 is of variable length. If the upper conductor is rotated in a counterclockwise direction, then it will be displaced such that the shortest length of conductive pathway takes place between the input port 30 and the output port 32. However, if the upper conductor (FIG. 6) is rotated in a clockwise direction to its maximum extent, then this will result in the longest conductive pathway between the input port 30 and the output port 32. The longer the length of this pathway results in a lower center frequency of operation, whereas the shorter this length will provide a higher center frequency. Consequently, this provides a tunable inverter for changing the operating frequency over a frequency range. It has been determined that this frequency range may be on the order of 330 MHz to 1 GHz. This provides a substantially wider band range of operation than that obtained with a typical conventional Doherty power amplifier which, as noted hereinbefore, is limited to a range of approximately 10% bandwidth due to the necessary incorporation of the quarter wavelength transmission line structure. Thus, the center frequency may be adjusted by rotating the top structure relative to the bottom structure to provide a continuous 90° phase change across the frequency band. As noted, the frequency is determined by the length of the conductive pathway between the input port 30 and the output port 32.

From the above description of the invention, those skilled in the art will perceive improvements, changes, and modifications. Such improvements, changes and modifications within the scope of the art are intended to be covered by the appended claims.

Having described the invention, I claim:

1. A tunable impedance inverter for a Doherty amplifier circuit having first and second amplifiers connected in parallel between an input circuit for receiving an input signal and an output circuit for supplying an output signal to a load and an impedance inverter coupled between said first amplifier and said output circuit wherein said inverter has an input and an output and a tunable electrical strip line of variable length interposed between said input and said output and an adjuster for adjusting the length of said strip line and wherein said adjuster adjustably varies the length of said strip line to thereby vary the length of said pathway and adjust the center frequency of said output signal.

2. An inverter as set forth in claim 1 including first and second portions that are movable relative to each other, each said portion having a surface that faces a surface on said other portion, each said facing surface carries a conductor.

3. An inverter as set forth in claim 2 wherein said conductors on said facing surfaces are arranged to contact each other as said portions move relative to each other.

4. An inverter as set forth in claim 2 wherein said conductors on said facing surfaces contact each other for a variable amount as said portions move relative to each other.

5. An inverter as set forth in claim 4 wherein said conductor on a surface of said first portion includes first and second conductors.

6. An inverter as set forth in claim 5 wherein said first conductor is connected to said input and said second conductor is connected to said output.

7. A modified Doherty power amplifier circuit comprising:
a first amplifier;
a second amplifier;
an impedance inverter that combines an output signal of said first amplifier with an output signal of said second amplifier, said inverter, having an input and an output and an adjustable, variable length electrical pathway between said input and said output and an adjuster that varies said length of said electrical pathway

8. An inverter as set forth in claim 7 wherein said first and second portions are movable relative to each other, each said portion having a surface that faces a surface on said other portion, each said facing surface carries a conductor.

9. A circuit as set forth in claim 8 wherein said first and second amplifiers are connected together in parallel.

10. A circuit as set forth in claim 9 wherein said conductors on said facing surfaces are arranged to contact each other as said portions are moved relative to each other.

11. A circuit as set forth in claim 10 wherein said conductors on said facing surfaces contact each other for a variable amount as said portions move relative to each other.

12. A circuit as set forth in claim 11 wherein said conductor on a surface of said first portion includes first and second conductors.

13. A circuit as set forth in claim 12 wherein said first conductor is connected to said input and said second conductor is connected to said output.
